(19) United States
(12) Patent Application Publication
(10) Pub. No.: US 2025/0218830 A1
(43) Pub. Date: Jul. 3, 2025

(54) COMPONENT PROCESSING APPARATUS

(71) Applicant: PlayNitride Display Co., Ltd., MiaoLi County (TW)

(72) Inventors: Yen-Mu Chen, MiaoLi County (TW); Yi-Ching Chen, MiaoLi County (TW); Han-Cheng Tsou, MiaoLi County (TW)

(73) Assignee: PlayNitride Display Co., Ltd., MiaoLi County (TW)

(21) Appl. No.: 18/396,715

(22) Filed: Dec. 27, 2023

(51) Int. Cl. H01L 21/67; B23K 1/00; B23K 1/005; B23K 1/018; B23K 3/08; B23K 101/40; H01L 21/66; H01L 21/683; H01L 25/075

(52) U.S. Cl. CPC H01L 21/67288; B23K 1/0016; B23K 1/0056; B23K 1/018; B23K 3/08; H01L 21/67115; H01L 22/22; B23K 2101/40; H01L 21/6835; H01L 25/0753; H01L 2221/68381

(57) ABSTRACT

A component processing apparatus including a carrying unit, a control unit and a processing module is provided. The carrying unit is adapted to carry an object to be processed. The control unit is signally connected to the carrying unit and defines a surface of the object to be processed as a plurality of processing areas. The processing module is controlled by the control unit. The processing module includes a transfer unit and a repair unit. The transfer unit is adapted to configure a plurality of components to each processing area according to a set sequence between the plurality of processing areas. The repair unit and the transfer unit process the object to be processed synchronously. Additionally, the repair unit removes a part of the components configured by the transfer unit in each processing area, or configures another component to a vacant position in each processing area.

### BACKGROUND

### Technical Field

This disclosure relates to a component processing apparatus, and in particular to a component processing apparatus including a transfer unit and a repair unit.

### Description of Related Art

In recent years, micro LED displays have gradually attracted the investment attention of major technology companies. Unlike a traditional thin-film transistor display, each pixel of a micro LED display includes of a plurality of light-emitting chips. As such, mass transfer could be a key technology in the field.

Currently, the difficulties of the mass transfer of technology may be roughly divided into two aspects. Firstly, the precision (yield) of the transfer is insufficient, and an additional mass repair process could be required to meet the requirements of commercial grade. Secondly, the mass repair process and related detection processes are time-consuming. Moreover, as display pixels increase, the number and difficulty of repairing each wafer increases significantly, resulting in high costs.

### SUMMARY

The disclosure provides a component processing apparatus, which may perform a detection process and a repair process synchronously during a mass transfer process, thereby a process efficiency may be improved.

The component processing apparatus of the disclosure includes a carrying unit, a control unit, and a processing module. The carrying unit is used to carry the object to be processed. The control unit is signally connected to the carrying unit and defines a surface of the object to be processed as a plurality of processing areas. The processing module is controlled by the control unit. The processing module includes a transfer unit and a repair unit. The transfer unit is suitable for arranging a plurality of components to each processing area according to a set sequence between the plurality of processing areas. The repair unit processes the object to be processed with the transfer unit synchronously. Moreover, the repair unit removes a portion of the components arranged by the transfer unit in each processing area, or arranges another component to one of the vacant positions in each processing area.

Based on the above, in an embodiment of the component processing apparatus of the disclosure, the transfer unit and the repair unit may perform corresponding processes (e.g., a transfer process and a repair process) synchronously in different processing areas. Therefore, a processing efficiency of the component processing apparatus may be improved, and the throughput may be correspondingly increased.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a partial three-dimensional schematic diagram of a component processing apparatus and a corresponding object to be processed according to an embodiment of the disclosure.

FIG. 1B is a partial system schematic diagram of a component processing apparatus according to an embodiment of the disclosure.

FIGS. 2A and 2B are partial side view schematic diagrams of a component processing apparatus performing a mass transfer process according to an embodiment of the disclosure.

FIGS. 3A and 3B are partial side view schematic diagrams of a component processing apparatus performing a detection process according to an embodiment of the disclosure.

FIGS. 4A and 4B are partial side view schematic diagrams of a component processing apparatus performing a mass repair process according to an embodiment of the disclosure.

FIG. 5A is a partial three-dimensional schematic diagram of a component processing apparatus performing a process of the component on the object to be processed according to an embodiment of the disclosure.

FIG. 5B is a schematic diagram of a processing path of the object to be processed by the component processing apparatus in FIG. 5A.

FIG. 6A is a partial three-dimensional schematic diagram of the component processing apparatus rotating the object to be processed in FIG. 5A.

FIG. 6B is a schematic diagram of a processing path of the object to be processed by the component processing apparatus in FIG. 6A.

FIG. 7 is a schematic diagram of a component processing apparatus performing a mass transfer process and a mass repair process synchronously according to an embodiment of the disclosure.

FIG. 8A is a partial three-dimensional schematic diagram of a component processing apparatus performing a process of the component on the object to be processed according to another embodiment of the disclosure.

FIG. 8B is a schematic diagram of a processing path of the object to be processed by the component processing apparatus in FIG. 8A.

FIG. 9 is a top view schematic diagram of a component processing apparatus performing a process of the component on the object to be processed according to yet another embodiment of the disclosure.

FIGS. 10A and 10B are top view schematic diagrams of a processing method in the embodiment of FIG. 9.

FIGS. 11A and 11B are top view schematic diagrams of another processing method in the embodiment of FIG. 9.

FIGS. 12A and 12B are top view schematic diagrams of yet another processing method in the embodiment of FIG. 9.

### DESCRIPTION OF THE EMBODIMENTS

The following description may be referred to the drawing of this implementation example to more comprehensively explain the disclosure. However, this disclosure may also be embodied in various different forms and should not be limited to the implementation examples described in the description. The sizes of some components, layers, or regions in the drawing may be enlarged for clarity. The same or similar reference numbers may indicate the same or similar components, and the following paragraphs will not elaborate on them one by one. In addition, the directional terms mentioned in the implementation examples, such as: up, down, top, or bottom, etc., are only for reference to the direction of the drawings. Therefore, unless specifically stated, the directional terms used are for explanation and not for limiting this disclosure. Moreover, to clearly indicate the directional relationship between different drawings, in some drawings, the corresponding directions are exemplarily represented by a Cartesian coordinate system (e.g., XYZ rectangular coordinate system), but this disclosure is not limited thereto.

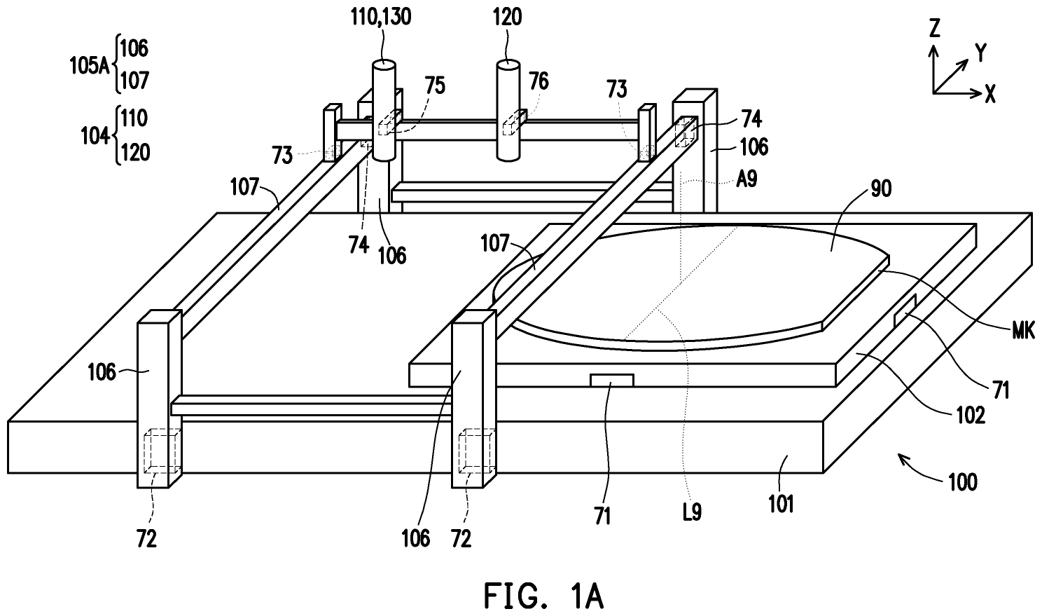

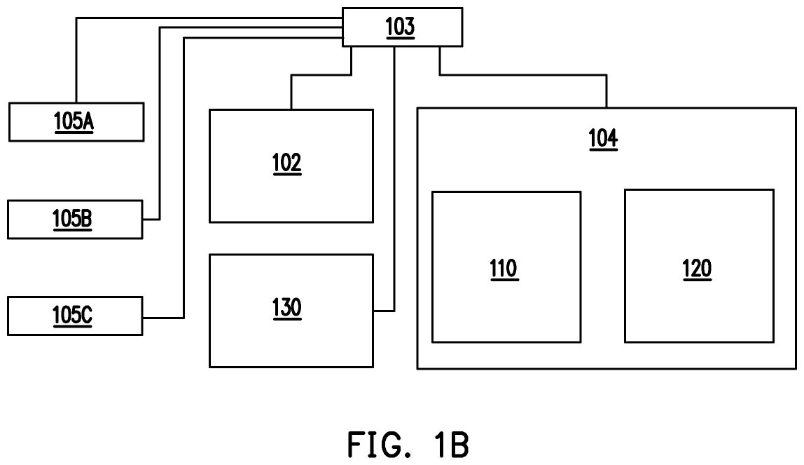

FIG. 1A is a partial three-dimensional schematic diagram of a component processing apparatus and a corresponding object to be processed according to an embodiment of the disclosure. FIG. 1B is a partial system schematic diagram of a component processing apparatus according to an embodiment of the disclosure.

Referring to FIGS. 1A and 1B, a component processing apparatus 100 includes a carrying unit 102, a control unit 103, and a processing module 104.

The control unit 103 may include corresponding hardware and/or software, and may perform input, output, computation, storage, monitoring, data collection, statistics, and/or other appropriate operations. In an embodiment, the control unit 103, for example, includes software suitable for logical judgment or a platform suitable for advanced process control (APC) and/or programmable logic controller (PLC), but the disclosure is not limited thereto.

The control unit 103 is signally connected to the carrying unit 102 and the processing module 104, and causes the carrying unit 102 and the processing module 104 to perform actions such as moving, rotating, emitting corresponding processing beams, or performing corresponding sensing, but the disclosure is not limited thereto.

The carrying unit 102 may carry the object to be processed 90. The object to be processed 90 may be an intermediary substrate in a mass transfer process, or a display panel in a mass repair process, but the disclosure is not limited thereto. The control unit 103 may define a surface of the object to be processed 90 as a plurality of processing areas through corresponding hardware and/or software. In the embodiment, the plurality of processing areas may be located on a single board, but the disclosure is not limited thereto. Specifically, the dotted line L9 as shown in FIG. 1A or other similar drawings may serve as a virtual line distinguishing different processing areas on a same board; but in other embodiments, the plurality of processing areas may also belong to different boards carried by the carrying unit 102; that is, the dotted line L9 as shown in FIG. 1A or other similar drawings may represent the gap between adjacent different boards, or other physical mechanisms.

In an embodiment, the carrying unit 102 is movably configured on the substrate platform 101, and may be driven to move or rotate the object to be processed 90 by a corresponding movable part 71 (e.g., a motor, a roller, a ball, a gear, a gear track, a toothed belt, a belt, etc., but not limited). The carrying unit 102 may translate in the X direction and/or Y direction along the XY plane. In addition, to increase process flexibility, the carrying unit 102 may also rotate relative to the substrate platform 101 according to the rotational axis A9, and the axial direction of the rotational axis A9 is perpendicular to the XY plane, but the disclosure is not limited thereto. In other embodiments not shown, the relative movement relationship between the carrying unit 102 and the substrate platform 101 may also be realized by adopting any movable structure design known to a person having ordinary skill in the disclosure. In addition, for simplicity, the movable part 71 in the drawing is only shown for illustrative purposes, and other movable parts similar to the movable part 71 may be omitted from the drawing.

The processing module 104 includes a transfer unit 110 and a repair unit 120. The transfer unit 110 and the repair unit 120 are movably configured on a movable platform 105A. The movable platform 105A may be a gantry type movable platform including a corresponding support column 106 and a corresponding crossbeam 107, but the disclosure is not limited thereto. Through the movable parts 72, 73, and 74 of the movable platform 105A, the processing module 104 configured thereon may be moved in the X, Y, and Z directions relative to the substrate platform 101, respectively. In addition, through the movable parts 75 and 76, the transfer unit 110 and the repair unit 120 may be translated in the XZ plane, respectively. That is, the planes in which the carrying unit 102 and the processing module 104 move may be orthogonal to each other. With the movement of the movable parts 71 and/or 72 in the XY plane, the transfer unit 110 and the repair unit 120 may achieve three-dimensional movement relative to the object to be processed, and perform a transfer process and/or a repair process on the plurality of processing areas on the XY plane, including but not limited to using a line-by-line scanning method. Moreover, the transfer unit 110 and the repair unit 120 may operate synchronously at different locations (e.g., both sides of the object to be processed 90 in the X direction). In addition, for simplicity, the movable parts 72, 73, 74, 75 and 76 in the drawings are only shown for illustrative purposes, and other movable parts similar to the movable parts 72, 73, 74, 75 and 76 may be omitted.

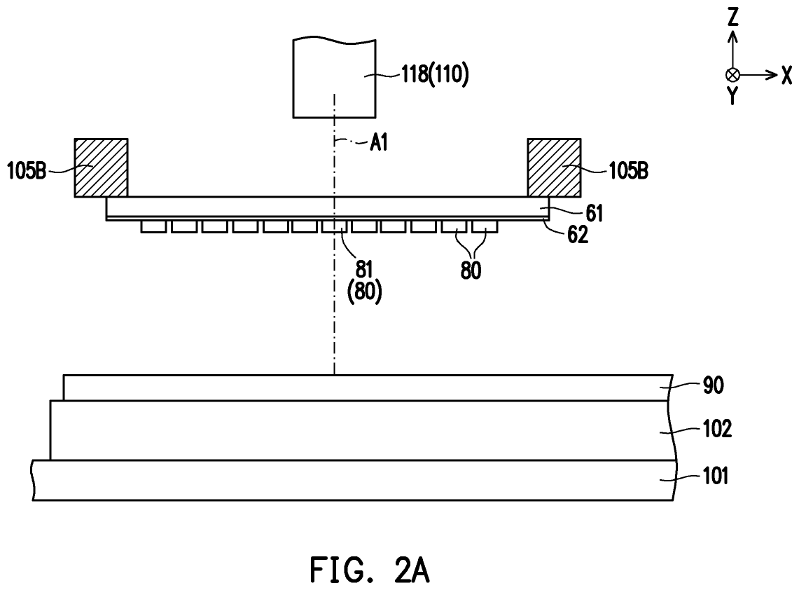

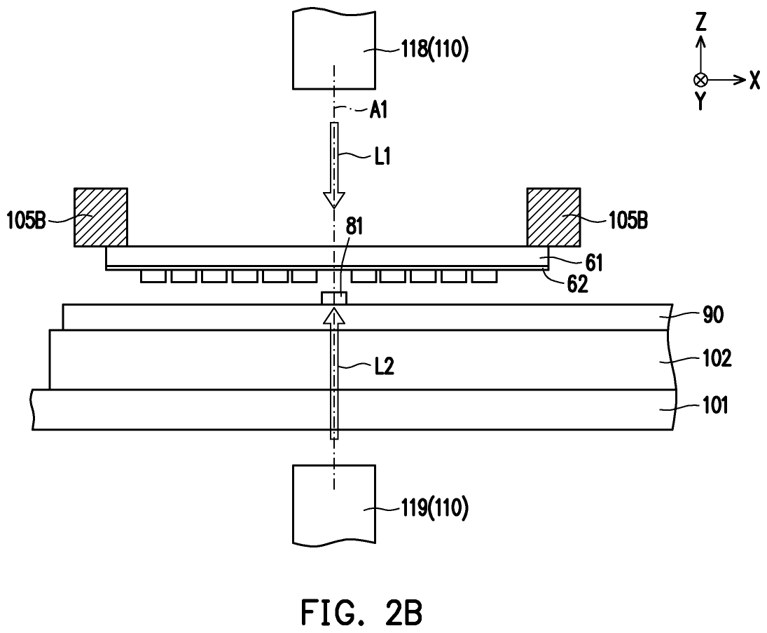

The transfer unit 110 is suitable for arranging a plurality of components to the object to be processed 90 according to a sequence set in the control unit 103. For example, the transfer unit 110 is suitable for arranging the plurality of components to each processing area and/or corresponding position according to the set sequence and/or corresponding arrangement pattern between the plurality of processing areas. The component is, for example, a micro light-emitting diode (μLED), but the disclosure is not limited thereto. For example, referring to FIG. 2A, a temporary carrier 61 with the corresponding components 80 may be configured on another movable platform 105B, which is, for example, a gantry type movable platform, and a crossbeam (not shown) thereof has another extension direction (e.g., along the X direction). The transfer unit 110 may have corresponding laser sources 118 and 119. By the relative movement between the movable platform 105A and the movable platform 105B, the laser source 118 may be aligned with a certain component 81 (one of the components 80) on the temporary carrier 61. Referring to FIG. 2B, the temporary carrier 61 is brought close to the processing area of the object to be processed 90, and the adhesiveness of a portion of a adhesive layer 62 between the component 81 and the temporary carrier 61 may be reduced or invalidated by a transfer beam L1 emitted by the laser source 118, so that the component 81 to be transferred is placed on the processing area of the object to be processed 90. By corresponding movement, the laser source 119 may be aligned with the component 81 on the temporary carrier 61. The laser sources 118 and 119 may be coaxial (that is, they have the same optical axis A1). The component 81 and the object to be processed 90 may be soldered by an irradiation of a corresponding solder beam L2 (for example, the pre-set metal pad on the object to be processed 90 is melted). In this way, the component 81 may be transferred from the temporary carrier 61 to the corresponding processing area in the object to be processed 90.

It is worth noting that in the embodiment, the light sources of the transfer beam L1 and the solder beam L2 are respectively located above and below the object to be processed 90. However, in an unillustrated embodiment, the positions of the light sources of the transfer beam L1 and the solder beam L2 may also be interchanged. That is, the light source of the transfer beam L1 is located below the object to be processed 90, and the light source of the solder beam L2 is located above the object to be processed 90, but not limited to this. For example, the light sources of the transfer beam L1 and the solder beam L2 may also be located on a same side of the object to be processed 90, and the same-side configuration of the light sources may be achieved by using a tilted laser processing.

During a mass transfer process, it cannot be guaranteed that each component 80 is transferred successfully; that is, some components 80 may fail to be transferred for various reasons. The aforementioned failed transfer may include but is not limited to: failure of component transfer, damage or destruction of the component after transfer, component offset, or other unknown reasons for component failure.

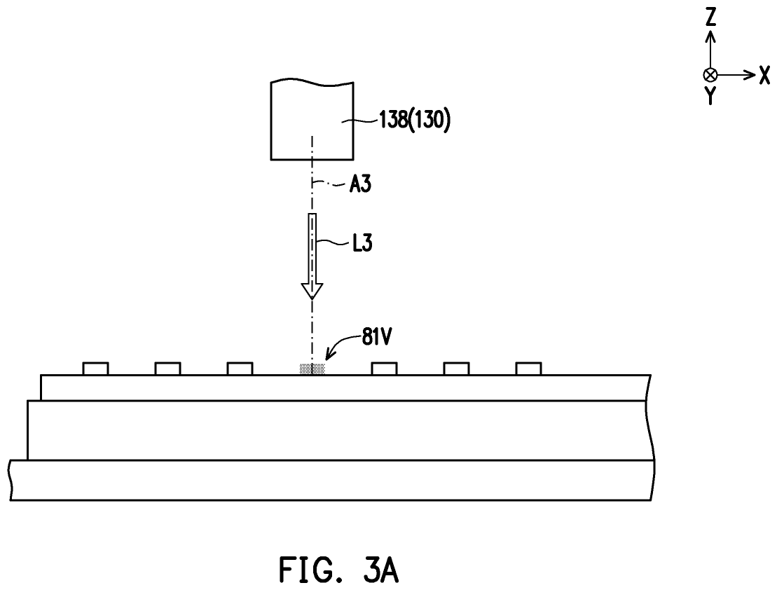

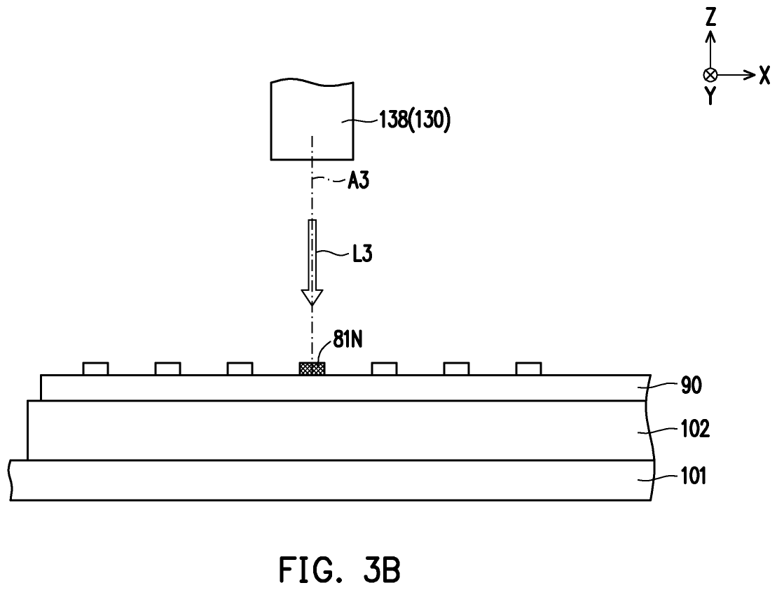

Referring to FIGS. 1A, 1B, and 3A, the component processing apparatus 100 of this embodiment may further include a detection unit 130. The control unit 103 is signally connected to and controls the detection unit 130. The detection unit 130 may have a corresponding laser source 138 to emit a detection beam L3, and the control unit 103 may receive detection data from the detection unit 130 to determine whether the component 80 has been successfully transferred. In addition, the detection unit 130 may be integrated with the transfer unit 110 in a same module, so as to synchronously perform an appropriate detection process on the transferred component through the detection unit 130 when the transfer unit 110 is performing the transfer process. The detection means includes, for example, measuring the electrical properties of the component 80 with a probe, measuring brightness or light field of the component 80 with electroluminescence testing, testing the photoexcitation and spectrum of the component 80 with photoluminescence testing, or capturing images of transfer or repair with a charge-coupled device (CCD), but the disclosure is not limited to hereabove. Moreover, if a component fails to be transferred, the control unit 103 may control the repair unit 120 to perform a repair processing on the failure site based on the detection data (e.g., the position of the failure site, the type of failure, etc.). In an embodiment, the optical axis A1 of the laser source 118 (as shown in FIG. 2A or FIG. 2B) and the optical axis A3 of the laser source 138 may be coaxial or close. For example, a design of scanning galvanometer and optical lens group may be used to achieve coaxial optical path; or, a design of mechanism integration may be used to keep light sources thereof coaxial during the movement of the platform.

For example, as shown in FIG. 3A, after being irradiated by the detection beam L3 from the laser source 138, if the control unit 103 determines that there should be a component but actually not, then this place may be referred to as a vacant position 81V. Referring to FIG. 3B, if the transferred component 81N is determined to be damaged, defective, broken, or other abnormalities, then this point may be referred to as a dead pixel, and a removal process of the component 81N needs to be performed first.

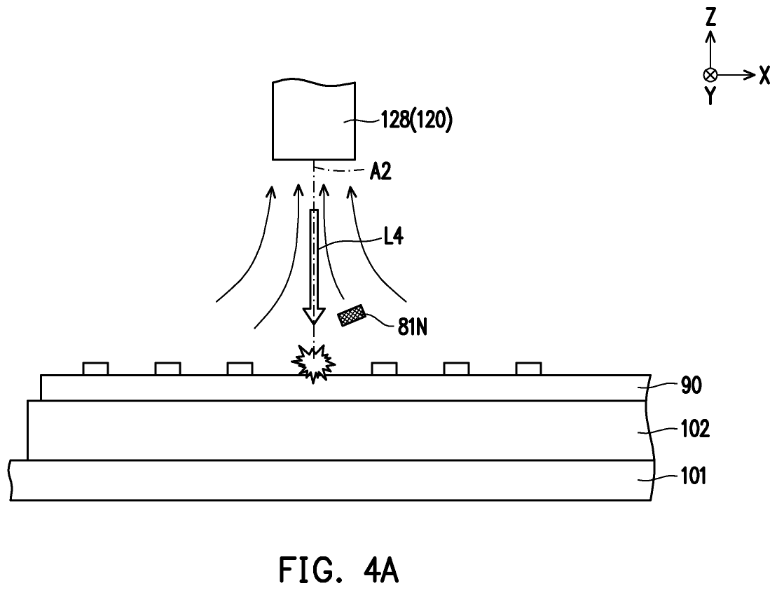

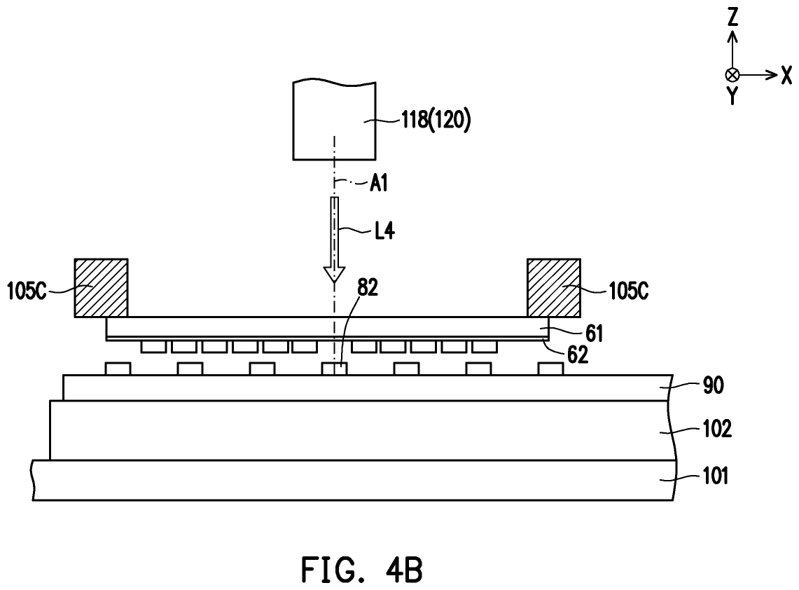

For example, as shown in FIG. 4A, the laser source 128 of the repair unit 120 emits a repair beam LA to desolder and remove the damaged or defective component 81N, and the component 81N is recovered by means such as vacuum suction, thereby repairing the dead pixel to a vacant position.

Referring to FIG. 4B, a temporary carrier 61 adhered with a corresponding other component 82 may be configured on another movable platform 105C, which is, for example, a gantry type movable platform, and a crossbeam (not shown) thereof has another extension direction (e.g., along the X direction). The repair unit 120 may be equipped with a corresponding laser source 118; that is, the repair unit 120 is considered as another transfer unit when cooperating with the movable platform 105C. By the relative movement between the movable platform 105A and the movable platform 105C, the optical axis A1 of the laser source 118 may be aligned with one of the components 80 on the temporary carrier 61 (e.g., the components 82), and the component is transferred from the temporary carrier 61 to the corresponding processing area in the object to be processed 90 by the transfer beam L1, thereby the corresponding repair process is completed.

Furthermore, since the mass transfer process and the mass repair process are performed synchronously, therefore, at least under a manner that the above-mentioned processes performed synchronously, the movable platform 105B suitable for the transfer unit 110 and the temporary carrier 61 configurated thereon, and the movable platform 105C suitable for the repair unit 120 and the temporary carrier 61 configurated thereon are two sets groups of independently configured. In this way, the transfer unit 110 and the repair unit 120 may perform corresponding processing (e.g., the transfer process and the repair process) synchronously in different processing areas. Therefore, the processing efficiency of the component processing apparatus 100 may be improved, and the throughput may be correspondingly increased. Since the process of the repair unit 120 configuring another repair component to the vacant position essentially belongs to a component transfer process (e.g., the process as shown in FIG. 4B), the same laser source of the processing module 104 may be used by the transfer unit 110 and the repair unit 120, and then each is equipped with an appropriate optical path design to process the object to be processed 90.

Furthermore, for simplicity of description, the removal process as shown in FIG. 4A and the repair process as shown in FIG. 4B are both performed from the top side of the object to be processed 90. However, in other unillustrated component processing apparatus (similar to the component processing apparatus 100), the mechanisms related to the removal process and the repair process may also be configured on both sides of the object to be processed 90. In this way, when the transfer unit (similar to the transfer unit 110) performs the transfer process, the repair unit (similar to the repair unit 120) may synchronously remove abnormal components from the other side of the object to be processed 90.

The following description will illustratively disclose a process performed by the component processing apparatus 100 on the object to be processed 90. For clarity, some components, parts, or module may be omitted from the subsequent drawings.

Furthermore, to clearly determine the orientation of the object to be processed 90, a corresponding position mark MK may be depicted in the drawings. In the embodiment, the orientation and position of the object to be processed 90 are determined by the control unit 103 based on the wafer flat of the object to be processed 90. However, depending on the different objects to be processed (similar to the different objects to be processed 90), the determination method may be different, such as using an orientation pattern or a wafer notch.

Furthermore, for simplicity and consistency in the description, the representation and labeling rule of the components on the object to be processed 90 in the drawings are explained as follows. Those with solid outline lines and filled in blank are components that have been successfully transferred to the object to be processed 90 (e.g., components with the following symbols: Gn, where n is the corresponding number, such as: G01); a corresponding transfer process may be described previously. Those without outline lines and filled in dots are vacant positions (e.g., vacant positions with the following symbols: Vn, where n is the corresponding number, such as: V01), a corresponding repair process may be described previously. Moreover, for the same or similar position, the corresponding repaired component (e.g., a repaired component with the following symbols: RVn, where n is the corresponding number, such as: RV01) is labeled with a similar symbol. For example, the component RV01 is corresponded to the transfer and repair at the vacant position V01, and the rest may be inferred in the same rule. Those with solid outline lines and filled in grid are components that have been transferred to the object to be processed 90 but are damaged or defective (e.g., damaged or defective components with the following symbols: Nn, where n is the corresponding number, such as: N01), a corresponding removal process and a subsequent repair process may be described previously. Moreover, for the same or similar positions, the corresponding repaired component (e.g., repaired components with the following symbols: RNn, where n is the corresponding number, such as: RN01) is labeled with a similar symbol. For example, the component RN01 is the component N01 that has been removed due to damage or breakage, and then transferred and repaired, and the rest may be inferred in the same rule.

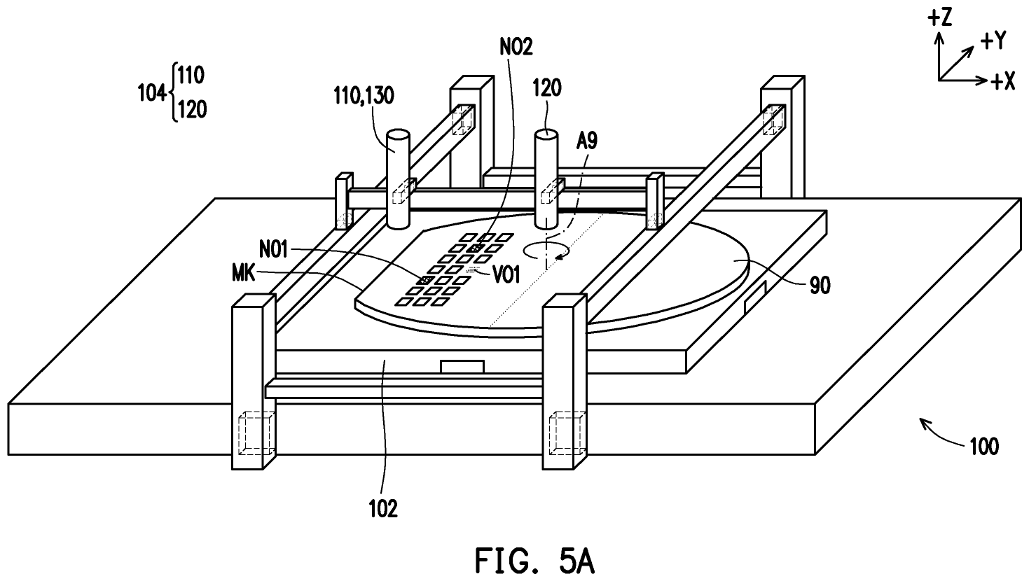

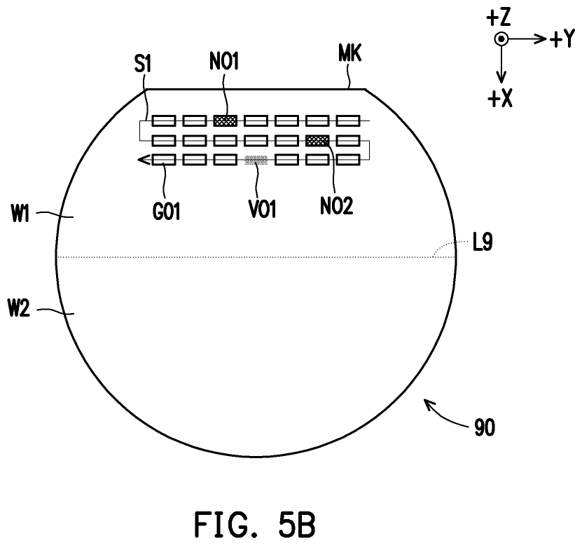

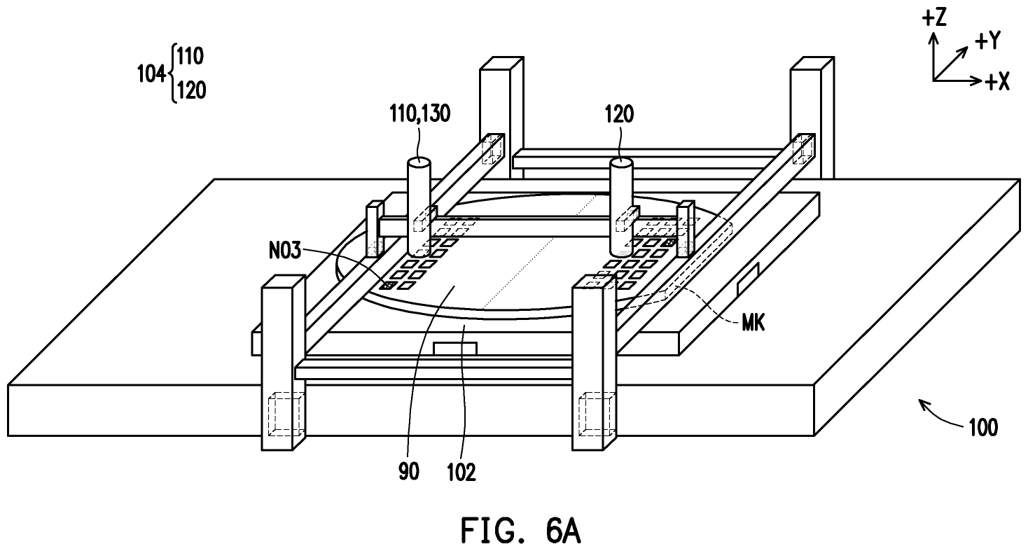

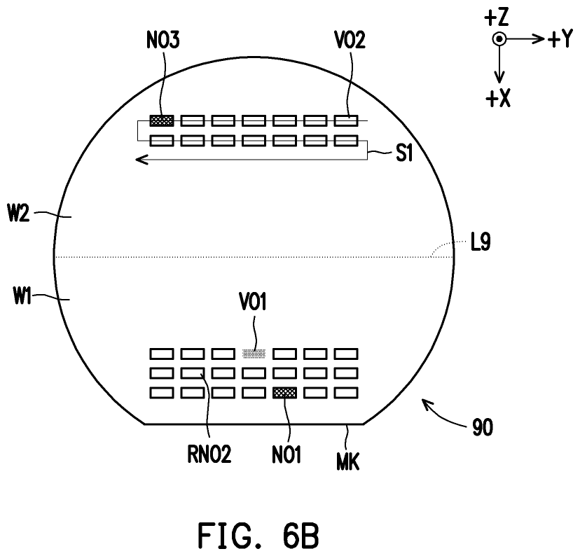

FIGS. 5A to 7 illustrate the process of a component processing apparatus 100 of an embodiment of the disclosure performing a mass transfer process and a mass repair process synchronously on an object to be processed 90. For example, FIGS. 5B and 6B may be top view schematic drawings corresponding to the object to be processed 90 in FIGS. 5A and 6A, respectively.

Referring to FIGS. 1, 5A, and 5B, after configuring the object to be processed 90 on the carrying unit 102, relative movement may be generated between the carrying unit 102 and the processing module 104 in an appropriate manner (e.g., the carrying unit 102 moving in the −X direction, the processing module 104 moving in the +X direction), so that the transfer unit 110 may perform a transfer process on the component as shown in FIGS. 2A and 2B.

The surface of the object to be processed 90 may be defined as a first processing area W1 and a second processing area W2. The range of the first processing area W1 may be roughly the same as the range of the second processing area W2. Moreover, the transfer unit 110 may first transfer the components in the first processing area W1 according to the first sequence S1. Here, the first sequence S1 is depicted symbolically, and the actual processing sequence of the processing module 104 may be adjusted. For example, in a subsequent embodiment, the transfer unit 110 may transfer components in a regular array pattern according to a different setting. That is, the first sequence S1 includes but is not limited to the distribution of components in rows and columns, staggered distribution, or other regular distributions.

After the transfer process being performed, most of the positions in the first processing area W1 are occupied by successfully transferred components G01, and there may be one or more damaged or defective components (e.g., the damaged or defective components N01, N02), and/or one or more vacant positions (e.g., the vacant position V01).

Referring to FIG. 6A, the carrying unit 102 and the object to be processed 90 configured thereon may be rotated along the rotational axis A9 as shown in FIG. 5A by an appropriate method for a subsequent repair process. Specifically, before the rotation (as shown in FIGS. 5A/5B), the transfer unit 110 corresponds to the first processing area W1, and the repair unit 120 corresponds to the second processing area W2; after the rotation is completed (as shown in FIGS. 6A/6B), the transfer unit 110 corresponds to the second processing area W2, and the repair unit 120 corresponds to the first processing area W1. Moreover, for the same processing area, the arrangement patterns formed by the plurality of components corresponding to the transfer unit 110 and the repair unit 120 are interchanged with the rotation of the rotational axis A9, and the arrangement patterns are centrosymmetric. That is, the rotation angle of the object to be processed 90 in FIG. 6B is 180 degrees compared to FIG. 5B. However, in other embodiments not shown, the object to be processed 90 may also be rotated at other angles, and the arrangement patterns corresponding to the transfer unit 110 and the repair unit 120 in this case are rotationally symmetric.

Referring to FIG. 6B, after the rotation is completed, the transfer unit 110 may transfer the components to the second processing area W2 according to the first sequence S1, but the disclosure does not limit the processing sequence to be the same. At the same time, the repair unit 120 repairs (as shown in FIGS. 4A to 4B) the damaged or defective components N01, N02, and the vacant position V01 of the object to be processed 90 in the first processing area W1. That is, the transfer unit 110 and the repair unit 120 may perform corresponding processes synchronously in different processing areas. It should be noted that FIG. 6B is a schematic drawing of a repair process of the repair unit 120, that is, the component RN02 is a repaired component, and the component N01 and the vacant position V01 are going to be repaired.

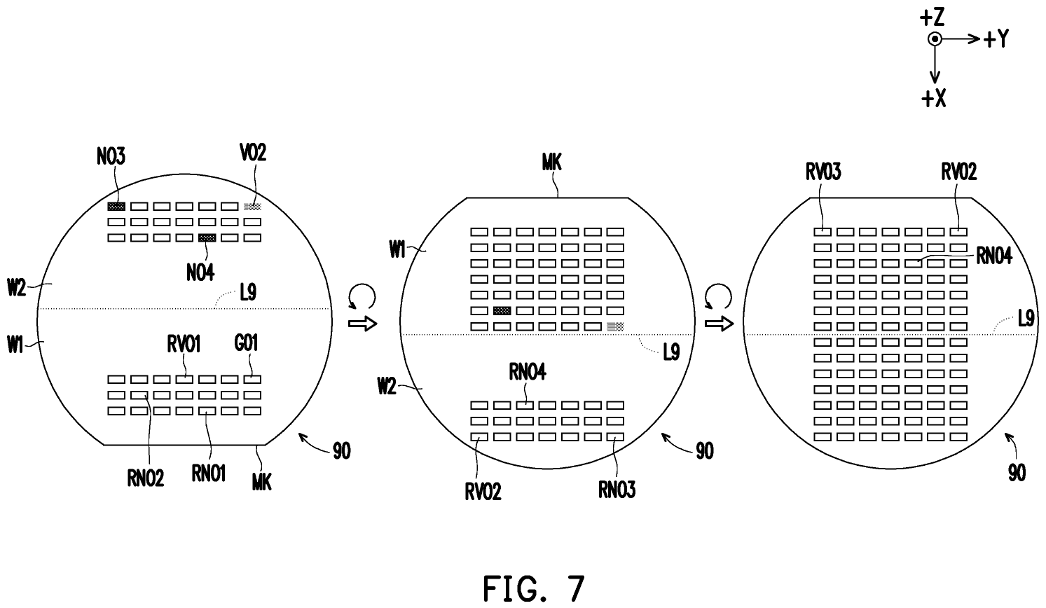

Referring to FIG. 7, after the components are transferred in the second processing area W2, new damaged or defective components N03, N04, and vacant position V02 may be generated. And, the positions to be repaired in the first processing area W1 are already configured with components RN01, RN02, and RV01. It is worth noting that the disclosure does not limit the order of completion of component repair in the first processing area W1 and the completion of component transfer in the second processing area W2.

Referring to FIG. 7 continuously, after a repair process of the component in the first processing area W1 being completed and a transfer process of the component in the second processing area W2 being completed, steps similar to those shown in FIGS. 5A to 6B may be performed, therefore the carrying unit 102 and the object to be processed 90 configured thereon are rotated again along the rotational axis A9, as such a subsequent repair process and/or a subsequent transfer process of the component may be performed.

After the transfer unit 110 further completes the transfer process of the component in the first processing area W1, the carrying unit 102 and the object to be processed 90 configured thereon are rotated again along the rotational axis A9 (not shown), as such a subsequent repair process and/or a subsequent transfer process of the component may be performed. By rotating the object to be processed 90 one or more times, the transfer unit 110 and the repair unit 120 may perform corresponding processes (e.g., the transfer process and the repair process) synchronously in different processing areas. In this way, the processing efficiency of the component processing apparatus 100 may be improved, and the throughput may be correspondingly increased. In addition, in the embodiment as shown in FIGS. 6A, 6B, and 7, only the object to be processed 90 is driven to rotate by the carrying unit 102, and the transfer unit 110 and the repair unit 120 do not move with the movement of the object to be processed 90. That is, the processing areas (e.g., the processing area W1 and the processing area W2) of the transfer unit 110 and the repair unit 120 exchange during the processing, but their processing areas at the same time are always different. In detail, the line L9 or other positioning markings may be used by the control unit 103 to limit the processing areas of the transfer unit 110 and the repair unit 120, to avoid collisions during synchronous processing. In this way, in configurations such as driving the transfer unit 110 and the repair unit 120 to move with the movable platform 105A, interference problems in mass transfer processes and mass repair processes may be avoided.

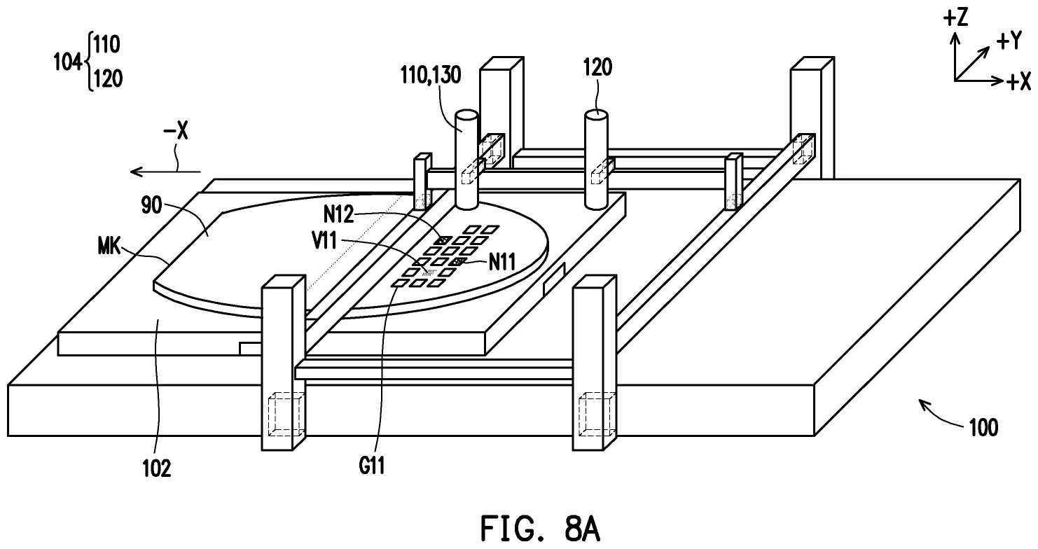

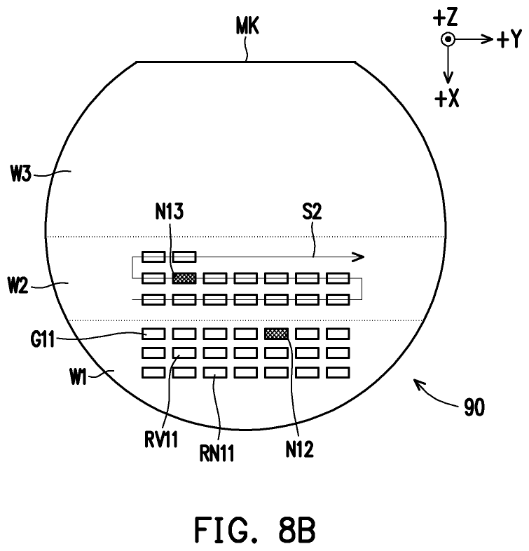

Referring to FIGS. 8A and 8B, in another embodiment of the disclosure, the transfer unit 110 may transfer components continuously according to a second sequence S2 in the second processing area W2 after completing the first processing area W1. Also, during the transfer process of the component in the first processing area W1, there may be some damaged or defective components N11, N12, and a vacant position V11. Similarly, FIG. 8B symbolically shows that the damaged or defective component N11 and the vacant position V11 have been repaired to the components RN11 and RV11 respectively, and the repair unit 120 is going to repair the damaged or defective component N12. The relative movement between the carrying unit 102 and the processing module 104 (e.g., the carrying unit 102 moves in the −X direction, and the processing module 104 moves in the +X direction) may make the transfer unit 110 correspond to the second processing area W2, and the repair unit 120 corresponds to the first processing area W1 to perform the repair process of the component synchronously. Then, the carrying unit 102 may move continuously in the −X direction, for example, so that when the transfer unit 110 corresponds to the third processing area W3, the repair unit 120 corresponds to the second processing area W2 for processing (e.g., repairing damaged or defective components N13) synchronously. In an embodiment, the transfer unit 110 may still transfer components according to the second sequence S2 in the third processing area W3.

Simply, in the embodiment as shown in FIGS. 8A and 8B, by moving the object to be processed 90 one or more times, the transfer unit 110 and the repair unit 120 may perform corresponding processes (e.g., the transfer process and the repair process) synchronously in different processing areas. In this way, the processing efficiency of the component processing apparatus 100 may be improved, which may correspondingly increase the throughput.

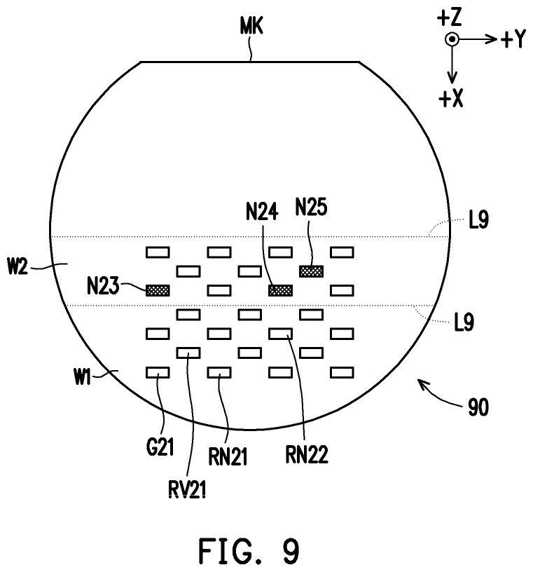

FIG. 9 is a top view schematic drawing of the component processing apparatus 100 performing a process of the component on the object to be processed 90 in another embodiment of the disclosure.

A process of the component and repair method as shown in FIG. 9 is similar to the aforementioned embodiments and will not be repeated here. The difference between the embodiment as shown in FIG. 9 and other embodiments is that a plurality of transferred components may be arranged at intervals in one direction (e.g., the X direction or Y direction). For example, the plurality of transferred components as shown in FIG. 9 are arranged in an alternating manner with default vacant positions. In this way, the heat generated during the transfer process of the components (e.g., soldering) is not excessively accumulated easily.

As the description of the previous embodiments, the first processing area W1 is in a state where the component transfer process and corresponding component repair process have been completed. Moreover, the second processing area W2 has completed the component transfer process and is ready to perform the corresponding component repair process.

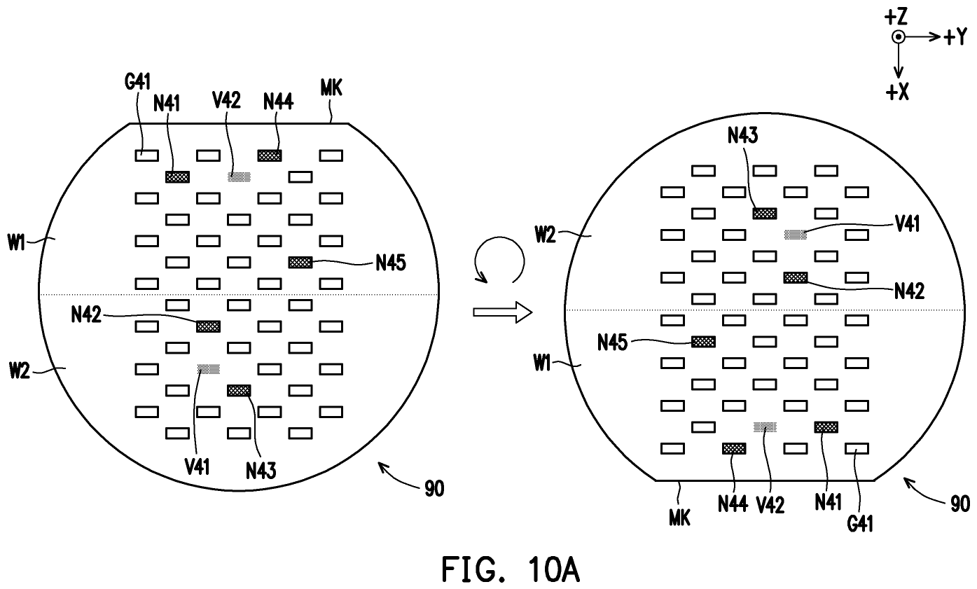

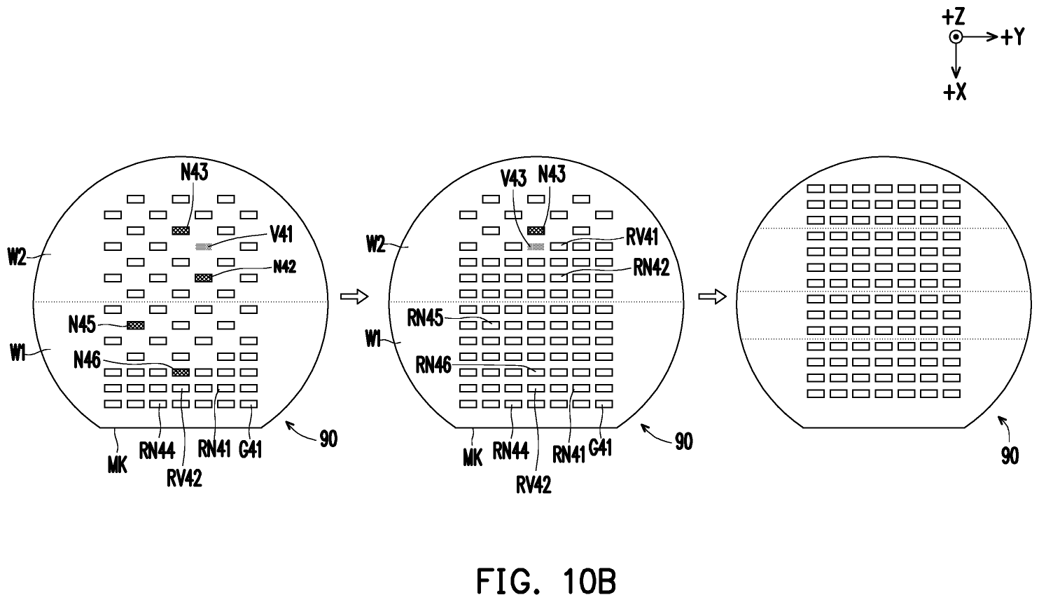

FIGS. 10A and 10B are top view schematic drawings of a processing method in the embodiment as shown in FIG. 9.

Referring to FIG. 10A, the object to be processed 90 may be moved relative to the processing module 104 in an appropriate manner. For example, in FIG. 10A, the object to be processed 90 is driven to move in the −X direction, so that the transfer unit 110 sequentially performs the transfer process on the first processing area W1 and the second processing area W2. In the processing method as shown in FIG. 10A, although a plurality of transferred components are arranged at intervals as shown in FIG. 9, the execution methods of the transfer process and the repair process may be varied. Specifically, when the interval transfer process is completed in the first processing area W1 and the second processing area W2, the repair process has not yet begun. Referring to FIG. 10B continuously, in a state when the transfer unit 110 is not moved, because the object to be processed 90 is rotated 180 degrees, the transfer unit 110 may again transfer the remaining parts (e.g., the default vacant positions as shown in FIG. 10A) from the first processing area W1 to the second processing area W2. At the same time, the repair unit 120 may also perform the repair process in the same direction. Here, the transfer unit 110 and the repair unit 120 may actually move relative to the object to be processed 90 by the aforementioned movable platform 105A, or they may perform the corresponding transfer and repair processes of the component by, for example, galvanometer scanning.

It is worth noting that as shown in FIG. 10B, the repair unit 120 may perform the corresponding process following the transfer unit 110 (and the detection unit 130). Therefore, although the damaged or defective component N46 and the vacant position V43 newly arise and are detected in the transfer process as shown in FIG. 10B, the repair unit 120 may repair the component N46 after sequentially repairing the components N44, N41, and V42. Similarly, after the components N45, N42 and the vacant position V41 are repaired, the vacant position V43 and the component N43 are subsequently repaired.

In this way, the repair unit 120 and the detection unit 130 not only process synchronously with the transfer unit 110, but also detect all the dead pixels or vacant positions generated during the transfer at the same time, and complete the repair process.

In addition, since the arrangement patterns of the transferred components as shown in FIGS. 10A and 10B are centrosymmetric or rotationally symmetric, this means that after the object to be processed 90 is rotated, the processing coordinates in the stage of FIG. 10B are the same as those in the stage of FIG. 10A. In this way, after the control unit 103 determine the position of the object to be processed 90 via the position mark MK, it may control the transfer unit 110, the repair unit 120, and the detection unit 130 to perform the process of the second stage directly. Moreover, after the process of the second stage is completed, all the components in the first processing area W1 and the second processing area W2 are automatically transferred and repaired.

Furthermore, as shown in FIGS. 9 to 10B and other embodiments descripted below, since both processing stages are performed from the first processing area W1 to the second processing area W2; considering that the repair unit 120 perform the repair process following the transfer unit 110, and the number of components in the repair process is far less than the number of components in the transfer process, the above processing method may ensure that each processing area has sufficient cooling time before the next processing stage, therefore avoiding the low transfer yield problem caused by thermal damage, thermal diffusion or other thermal stress accumulation caused by the dense arrangement of components in the transfer process (e.g., laser mass transfer).

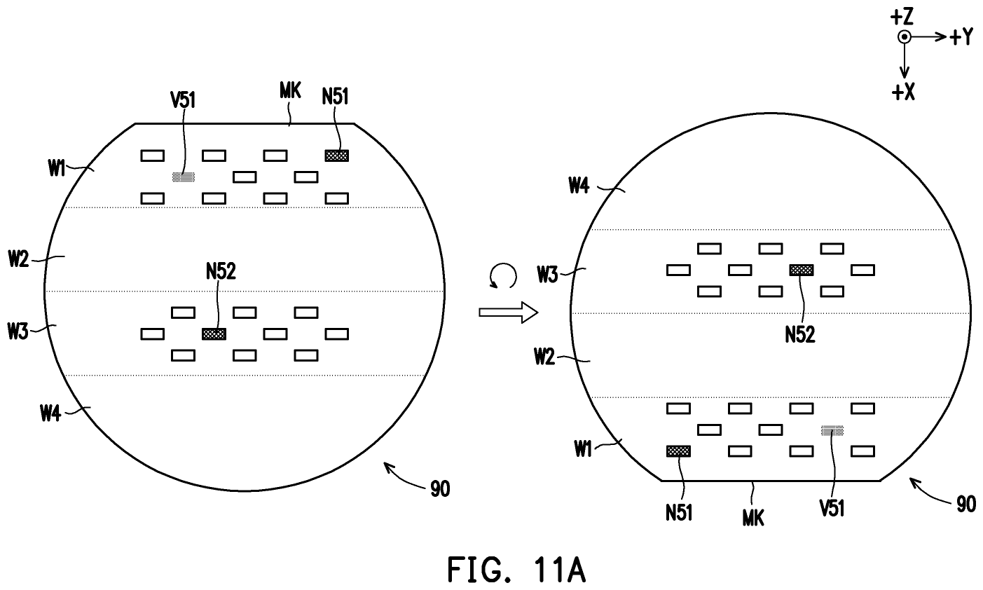

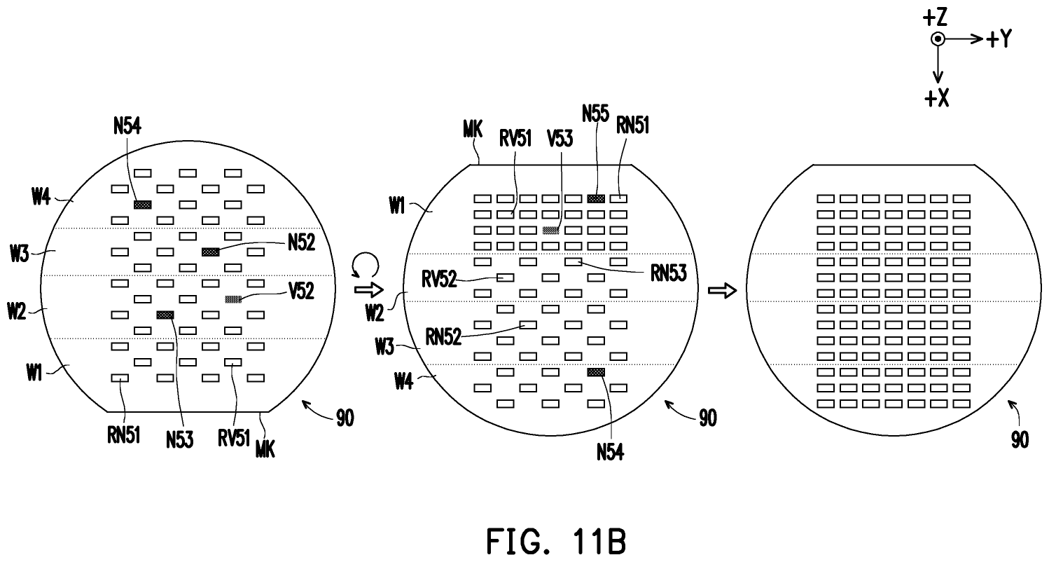

FIGS. 11A and 11B are top view schematic drawings of another processing method in the embodiment as shown in FIG. 9.

The processing method of one or more of the aforementioned embodiments may be integrated or adjusted, so that the transfer unit 110 and the repair unit 120 may perform corresponding processes (e.g., the transfer process and the repair process) synchronously in different processing areas, thereby improving the processing efficiency of the component processing apparatus 100. Taking the processing method in FIG. 11A as an example, the transfer process of the components may be performed in different processing areas (e.g., from the first processing area W1 to the third processing area W3) in a manner similar to that described in FIG. 10A. That is, within each processing stage, not only the components in the processing area may be arranged at intervals, but different processing areas may also be arranged at intervals. Then, referring to FIG. 11B, since the object to be processed 90 is rotated 180 degrees, similar to the method described in FIG. 10B, the transfer unit 110 perform the transfer process of components in other different processing areas (e.g., from the second processing area W2 to the fourth processing area W4). During this process, the repair unit 120 may perform the repair process in the transferred processing areas (e.g., the first processing area W1 and the third processing area W3) along the same direction. Referring to FIG. 11B continuously, since the object to be processed 90 is rotated 180 degrees again, the transfer unit 110 may transfer the components to the remaining parts (e.g., the default vacant positions in the right drawing as shown in FIG. 11A). At the same time, the repair unit 120 may also perform the repair process in the same direction. However, the same or similar to the previous description, the repair unit 120 may also perform the repair process to all transferred areas (along the first processing area W1 to the fourth processing area W4) at the same time while the transfer unit 110 is performing the transfer process to the second processing area W2 and the fourth processing area W4.

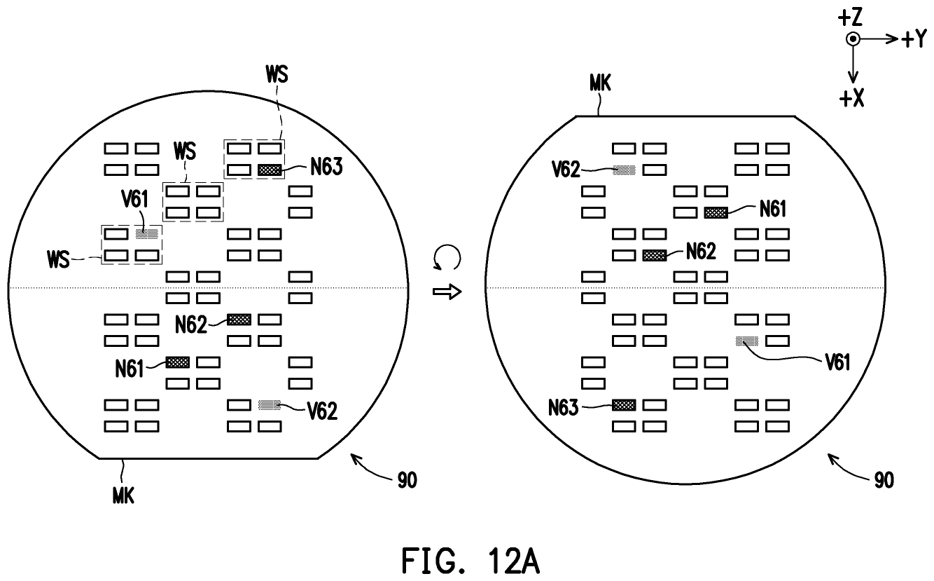

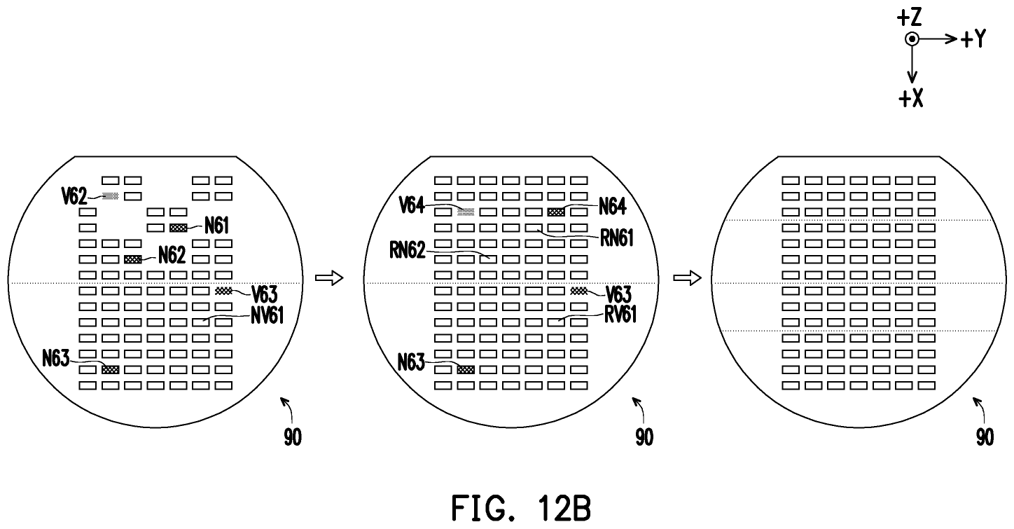

FIGS. 12A and 12B are top view schematic drawings of another processing method in the embodiment as shown in FIG. 9.

The processing method of one or more of the aforementioned embodiments may be integrated or adjusted, so that the transfer unit 110 and the repair unit 120 may perform corresponding processes (e.g., the transfer process and the repair process) synchronously in different processing areas, thereby improving the processing efficiency of the component processing apparatus 100. Taking the processing method in FIG. 12A as an example, the transfer process of the component may be performed in a manner similar to that described in FIG. 10A. The difference is that a plurality of components may form corresponding sub-processing areas WS, and the sub-processing areas WS are arranged at intervals. In other words, the transfer process, the detection process, or the repair process (may including the first sequence S1 or the second sequence S2 in the aforementioned embodiment) performed in one go by the processing module 104 of the disclosure is not limited to a single component. For example, the transfer beam L1, the solder beam L2, the detection beam L3, and the repair beam L4 may all be split into a plurality of beams through an optical beam splitter. Referring to FIG. 12B continuously, in a manner similar to that described in FIG. 10B, since the object to be processed 90 is rotated 180 degrees, the transfer unit 110 may transfer the component to the remaining part (e.g., the default vacant positions in FIG. 12A). At the same time, the repair unit 120 may also perform the repair process in the same direction.

In summary, in the component processing apparatus of the disclosure, the transfer unit and the repair unit are suitable for performing corresponding processing (e.g., transfer and repair) synchronously in a mass transfer process, thereby improving process efficiency and throughput.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A component processing apparatus, comprising:
a carrying unit, for carrying an object to be processed;
a control unit, signally connected to the carrying unit, and defining a surface of the object to be processed as a plurality of processing areas; and
a processing module, controlled by the control unit, and the processing module comprising:
a transfer unit, suitable for arranging a plurality of components to each of the processing areas according to a set sequence between the processing areas;
a repair unit, processing the object to be processed with the transfer unit synchronously, and removing a portion of the components arranged by the transfer unit in each of the processing areas, or arranging another component to one of vacant positions in each of the processing areas.

2. The component processing apparatus according to claim 1, wherein the carrying unit is controlled by the control unit and movable relative to the processing module, thereby the different processing areas of the object to be processed correspond to the transfer unit and the repair unit respectively.

3. The component processing apparatus according to claim 2, wherein the transfer unit and the repair unit are configured on both sides of the object to be processed.

4. The component processing apparatus according to claim 1, wherein the repair unit processes the object to be processed following the transfer unit according to at least a portion of the set sequence.

5. The component processing apparatus according to claim 4, wherein in one of the processing areas corresponding to the portion of the set sequence, a portion of the components corresponding to the transfer unit are arranged as a first arrangement pattern, and another portion of the components corresponding to the repair unit are arranged as a second arrangement pattern, wherein the first arrangement pattern and the second arrangement pattern are rotationally symmetrical to each other.

6. The component processing apparatus according to claim 4, wherein the set sequence comprises at least two processing areas, and the transfer unit and the repair unit process in different processing areas synchronously.

7. The component processing apparatus according to claim 4, wherein the carrying unit is configured on a rotational axis, and the processing areas corresponding to the transfer unit and the repair unit change with a rotation along the rotational axis.

8. The component processing apparatus according to claim 4, wherein the carrying unit suitable for translation along a first plane, the processing module suitable for translation along a second plane, and the first plane is orthogonal to the second plane.

9. The component processing apparatus according to claim 1, wherein the processing areas corresponding to the set sequence are arranged at intervals in one direction on the surface of the object to be processed.

10. The component processing apparatus according to claim 1, wherein in the set sequence, the transfer unit arranges the components in each of the processing areas in an alternating manner.

11. The component processing apparatus according to claim 1, further comprising:
a detection unit, controlled by the control unit, wherein the detection unit is suitable for performing detection means on each component with the transfer unit synchronously.

12. The component processing apparatus according to claim 11, wherein the control unit receives detection data from the detection unit and controls the repair unit to process based on the detection data.

13. The component processing apparatus according to claim 11, wherein both of the detection unit and the transfer unit have laser sources, and the detection unit performs the detection means on the components with the laser source thereof, the transfer unit arranges the components with the laser source thereof, wherein the laser source of the detection unit and the laser source of the transfer unit are coaxial on an optical axis of the object to be processed.

14. The component processing apparatus according to claim 1, wherein the repair unit has a laser source, and comprises a removal part and a repair part, the removal part is suitable for removing the portion of the components arranged by the transfer unit, the repair part is suitable for arranging the another component according to a position of each of the components removed by the removal part.

15. The component processing apparatus according to claim 14, further comprising:
a detection unit, having a laser source, the detection unit performs detection means on the components with the laser source thereof, and the laser source of the detection unit and the laser source of the repair unit are coaxial on an optical axis of the object to be processed.

16. The component processing apparatus according to claim 14, wherein the repair part and the transfer unit are configured on a side of the carrying unit, and the removal part is configured on another side of the carrying unit.

17. The component processing apparatus according to claim 14, wherein the repair part processes the position of each of the removed components following the removal part synchronously.

18. The component processing apparatus according to claim 1, wherein the processing module comprises a laser source, and the transfer unit and the repair unit are suitable for processing the object to be processed with the same laser source.

19. The component processing apparatus according to claim 1, further comprising:
a moving platform, suitable for carrying the components and moving relative to the object to be processed, wherein the moving platform positions at least one of each of the processing areas for the processing module to arrange the components to the processing area.
